(19) United States
(12) Patent Application Publication
(10) Pub. No.: US 2026/0291462 A1
(43) Pub. Date: Sep. 24, 2026

(54) ELECTRONIC COMPONENT

(71) Applicant: TDK Corporation, Tokyo (JP)

(72) Inventors: Tomonori TERUI, Tokyo (JP); Yuta ASHIDA, Tokyo (JP); Takuya SATO, Tokyo (JP); Masato YAMAGUCHI, Tokyo (JP)

(73) Assignee: TDK Corporation, Tokyo (JP)

(21) Appl. No.: 19/567,560

(22) Filed: Mar. 16, 2026

(30) Foreign Application Priority Data
Mar. 18, 2025 (JP) 2025-043385

(51) Int. Cl. H03H 9/05; H03H 9/46

(52) U.S. Cl. CPC H03H 9/0547; H03H 9/46

(57) ABSTRACT

An electronic component includes a first signal terminal, a second signal terminal, a ground terminal connected to a ground, a resonator provided between a path from the first signal terminal to the second signal terminal and the ground in a circuit configuration, and a connection conductor that includes a plurality of columnar conductors arrayed in parallel to each other and a conductor layer connected to the plurality of columnar conductors, and connects the resonator to the ground terminal.

### CROSS REFERENCE TO RELATED APPLICATIONS

This application claims the benefit of Japanese Priority Patent Application No. 2025-043385 filed on Mar. 18, 2025, the entire contents of which are incorporated herein by reference.

### BACKGROUND

The disclosure relates to an electronic component including a resonator connected to a ground terminal.

In a compact mobile communication apparatus, a configuration is widely used in which an antenna that is commonly used for a plurality of applications having different systems and operating frequency bands is provided, and a plurality of signals transmitted and received by the antenna are separated by using a branching filter.

In general, a branching filter that separates a first signal having a frequency within a first frequency band and a second signal having a frequency within a second frequency band higher than the first frequency band includes a common port, a first signal port, a second signal port, a first filter that is provided in a first signal path from the common port to the first signal port, and a second filter that is provided in a second signal path from the common port to the second signal port.

As the resonators used for first and second filters, for example, an LC resonator including an inductor and a capacitor and an acoustic wave resonator including an acoustic wave element are known. The acoustic wave element is an element using an acoustic wave. Examples of the acoustic wave element include a surface acoustic wave element using a surface acoustic wave and a bulk acoustic wave element using a bulk acoustic wave.

As the branching filter, there is one that is configured by using a low-temperature co-fired ceramics (hereinafter, also referred to as an “LTCC”) multilayer substrate. The LTCC multilayer substrate is manufactured by forming conductor layers having desired patterns on ceramic green sheets that later become dielectric layers, laminating a plurality of green sheets on which the conductor layers are formed, and co-firing the ceramic layers and the conductor layers.

JP 2006-129445 A discloses a branching filter in which a thin-film bulk acoustic wave resonator is placed in a cavity of a multilayer package. The thin-film bulk acoustic wave resonator includes a resonator provided between a path connecting an antenna terminal and a transmission/reception terminal to each other and a ground. Between the resonator and the ground, additional inductance formed by using a conductor pattern inside the package is provided. The conductor pattern is connected to a ground terminal formed on a back surface of the package.

When a resonator mounted on a top surface of a main body is connected to a ground terminal arranged on a bottom surface side of the main body, as in the branching filter of JP 2006-129445 A, a connection conductor provided inside the main body is used. The connection conductor includes an inductance component. Depending on the specifications of the branching filter, it is necessary to sufficiently reduce the inductance of the connection conductor.

In order to reduce the inductance of the connection conductor, it is conceivable to reduce the thickness of the main body and shorten the connection conductor. However, in the related art, components of the branching filter other than the resonator mounted on the top surface of the main body are provided inside the main body. Therefore, it is difficult to reduce the thickness of the main body while maintaining characteristics of the filter or the branching filter.

The problem described above is applicable not only to a case where the resonator is mounted on the top surface of the main body, but also to a case where the resonator is provided at a specific position inside the main body. The problem described above is applicable not only to a filter or a branching filter including a resonator, but also to an electronic component in general that includes a resonator directly or indirectly connected to a ground terminal.

### SUMMARY

An electronic component according to one embodiment of the disclosure includes a first signal terminal, a second signal terminal, a ground terminal connected to a ground, a resonator provided between a path from the first signal terminal to the second signal terminal and the ground in a circuit configuration, and a connection conductor that includes a plurality of columnar conductors arrayed in parallel and a conductor layer connected to the plurality of columnar conductors, and connects the resonator to the ground terminal.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the disclosure.

FIG. 1 is a circuit diagram showing a circuit configuration of the electronic component according to an example embodiment of the disclosure.

FIG. 2 is a perspective view showing the electronic component according to the example embodiment of the disclosure.

FIG. 3 is a cross-sectional view showing the electronic component according to the example embodiment of the disclosure.

FIG. 4 is a perspective view showing a stack in the example embodiment of the disclosure.

FIG. 5 is a perspective view showing the stack in the example embodiment of the disclosure.

FIG. 6 is an explanatory diagram showing a patterned surface of a first dielectric layer of the stack in the example embodiment of the disclosure.

FIG. 7 is an explanatory diagram showing a patterned surface of a second dielectric layer of the stack in the example embodiment of the disclosure.

FIG. 8 is an explanatory diagram showing a patterned surface of a third dielectric layer of the stack in the example embodiment of the disclosure.

FIG. 9 is an explanatory diagram showing a patterned surface of a fourth dielectric layer of the stack in the example embodiment of the disclosure.

FIG. 10 is an explanatory diagram showing a patterned surface of a fifth dielectric layer of the stack in the example embodiment of the disclosure.

FIG. 11 is an explanatory diagram showing a patterned surface of a sixth dielectric layer of the stack in the example embodiment of the disclosure.

FIG. 12 is an explanatory diagram showing a patterned surface of a seventh dielectric layer of the stack in the example embodiment of the disclosure.

FIG. 13 is an explanatory diagram showing a patterned surface of an eighth dielectric layer of the stack in the example embodiment of the disclosure.

FIG. 14 is an explanatory diagram showing a patterned surface of a ninth dielectric layer of the stack in the example embodiment of the disclosure.

FIG. 15 is an explanatory diagram showing a patterned surface of a tenth dielectric layer of the stack in the example embodiment of the disclosure.

FIG. 16 is an explanatory diagram showing a patterned surface of an eleventh dielectric layer of the stack in the example embodiment of the disclosure.

FIG. 17 is an explanatory diagram showing a patterned surface of a twelfth dielectric layer of the stack in the example embodiment of the disclosure.

FIG. 18 is an explanatory diagram showing a patterned surface of a thirteenth dielectric layer of the stack in the example embodiment of the disclosure.

FIG. 19 is an explanatory diagram showing a patterned surface of a fourteenth dielectric layer of the stack in the example embodiment of the disclosure.

FIG. 20 is an explanatory diagram showing a patterned surface of a fifteenth dielectric layer of the stack in the example embodiment of the disclosure.

FIG. 21 is an explanatory diagram showing a patterned surface of a sixteenth dielectric layer of the stack in the example embodiment of the disclosure.

FIG. 22 is an explanatory diagram showing a patterned surface of a seventeenth dielectric layer of the stack in the example embodiment of the disclosure.

FIG. 23 is an explanatory diagram showing a patterned surface of an eighteenth dielectric layer of the stack in the example embodiment of the disclosure.

FIG. 24 is an explanatory diagram showing a patterned surface of a nineteenth dielectric layer of the stack in the example embodiment of the disclosure.

FIG. 25 is an explanatory diagram showing a surface opposite to the patterned surface of the nineteenth layer of the stack in the example embodiment of the disclosure.

FIG. 26 is a perspective view showing an inside of the stack in the example embodiment of the disclosure.

FIG. 27 is a plan view showing a part of the stack in the example embodiment of the disclosure.

FIG. 28 is a perspective view showing a part of the stack in the example embodiment of the disclosure.

FIG. 29 is a perspective view showing a part of the stack in the example embodiment of the disclosure.

FIG. 30 is a perspective view showing a part of the stack in the example embodiment of the disclosure.

FIG. 31 is a characteristic chart showing an example of pass attenuation characteristics of the electronic component according to the example embodiment of the disclosure.

### DETAILED DESCRIPTION

An object of the disclosure is to provide an electronic component including a resonator connected to a ground terminal, the electronic component being capable of suppressing a problem caused by a connection conductor that connects the resonator to the ground terminal.

In the following, some example embodiments and modification examples of the disclosure will be described in detail with reference to the accompanying drawings. Note that the following description is directed to illustrative examples of the disclosure and not to be construed as limiting the disclosure. Factors including, without limitation, numerical values, shapes, materials, components, positions of the components, and how the components are coupled to each other are illustrative only and not to be construed as limiting the disclosure. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

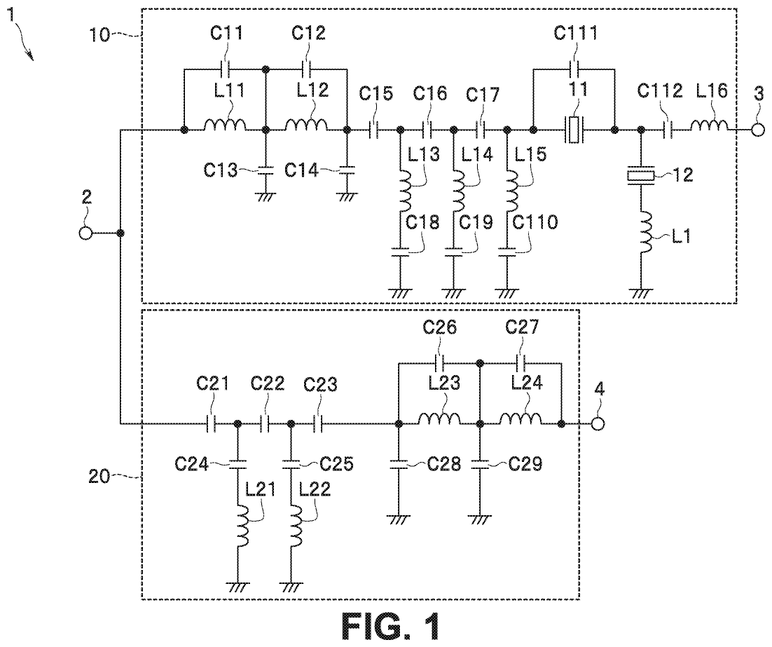

First, with reference to FIG. 1, a configuration of an electronic component 1 according to an example embodiment is described. FIG. 1 is a circuit diagram showing an example of a circuit configuration of the electronic component 1 according to the example embodiment. FIG. 1 shows a branching filter (diplexer) as an example of the electronic component 1. The electronic component 1 includes a first signal terminal 2, a second signal terminal 3, a third signal terminal 4, a first circuit 10, and a second circuit 20.

The first circuit 10 is provided between the first signal terminal 2 and the second signal terminal 3 in a circuit configuration. The second circuit 20 is provided between the first signal terminal 2 and the third signal terminal 4 in the circuit configuration. Note that, in the present application, the expression “in a circuit configuration” is used to describe an arrangement in a circuit diagram, not in a physical configuration.

The first circuit 10 is a filter that is configured to selectively cause a signal having a frequency within a first passband to pass through. The second circuit 20 is a filter that is configured to selectively cause a signal having a frequency within a second passband, which is different from the first passband, to pass through. In the example embodiment, the first and second circuits 10 and 20 are both band-pass filters. In the example embodiment, the first passband is a frequency band lower than the second passband.

The first signal terminal 2 is a common terminal for input or output of signals in a plurality of frequency bands. Each of the second and the third signal terminals 3 and 4 is a terminal for input or output of a signal in a specific frequency band. In the example embodiment, a first signal that has a frequency within the first passband and is input to the first signal terminal 2 selectively passes through the first circuit 10, and is output from the second signal terminal 3. A second signal that has a frequency within the second passband and is input to the first signal terminal 2 selectively passes through the second circuit 20, and is output from the third signal terminal 4. In this manner, the electronic component 1 separates the first signal and the second signal from each other.

The electronic component 1 further includes a path that extends from the first signal terminal 2 to the second signal terminal 3 and connects the first signal terminal 2 and the second signal terminal 3 to each other in the circuit configuration, a resonator 12 that is provided between the path and a ground, and an inductor L1 that is provided between the resonator 12 and the ground. The first circuit 10 includes the resonator 12 and the inductor L1. In addition to the inductor L1, another inductor or capacitor may be provided between the resonator 12 and the ground.

Next, with reference to FIG. 1, an example of a circuit configuration of the electronic component 1 is described. First, an example of a circuit configuration of the first circuit 10 is described. As described above, the first circuit 10 includes the resonator 12 and the inductor L1. The first circuit 10 further includes a resonator 11, inductors L11, L12, L13, L14, L15, and L16, and capacitors C11, C12, C13, C14, C15, C16, C17, C18, C19, C110, C111, and C112. The resonators 11 and 12 each include an acoustic wave element. The acoustic wave element may be a bulk acoustic wave element, or may be a surface acoustic wave element.

The inductors L11, L12, and L16, the capacitors C15, C16, C17, and C112, and the resonator 11 are provided in the path that extends from the first signal terminal 2 to the second signal terminal 3. The inductors L1, L13, L14, and L15 and the capacitors C13, C14, C18, C19, and C110 are provided between the above-mentioned path and the ground in the circuit configuration.

One end of the inductor L11 is connected to the first signal terminal 2. One end of the inductor L12 is connected to the other end of the inductor L11.

The capacitor C11 is connected in parallel to the inductor L11. The capacitor C12 is connected in parallel to the inductor L12. One end of the capacitor C13 is connected to a connection point between the inductor L11 and the inductor L12. One end of the capacitor C14 is connected to the other end of the inductor L12. The other end of the capacitor C13 and the other end of the capacitor C14 is connected to the ground.

One end of the capacitor C15 is connected to the other end of the inductor L12. One end of the capacitor C16 is connected to the other end of the capacitor C15. One end of the capacitor C17 is connected to the other end of the capacitor C16.

One end of the inductor L13 is connected to a connection point between the capacitor C15 and the capacitor C16. One end of the inductor L14 is connected to a connection point between the capacitor C16 and the capacitor C17. One end of the inductor L15 is connected to the other end of the capacitor C17.

One end of the capacitor C18 is connected to the other end of the inductor L13. One end of the capacitor C19 is connected to the other end of the inductor L14. One end of the capacitor C110 is connected to the other end of the inductor L15. The other end of the capacitor C18, the other end of the capacitor C19, and the other end of the capacitor C110 are connected to the ground.

One end of the resonator 11 is connected to the other end of the capacitor C17. The capacitor C111 is connected in parallel to the resonator 11. One end of the resonator 12 is connected to the other end of the resonator 11. One end of the inductor L1 is connected to the other end of the resonator 12. The other end of the inductor L1 is connected to the ground.

One end of the capacitor C112 is connected to the other end of the resonator 11. One end of the inductor L16 is connected to the other end of the capacitor C112. The other end of the inductor L16 is connected to the second signal terminal 3.

In the circuit configuration, the distance between each of the resonators 11 and 12 to the first signal terminal 2 may be larger than the distance between each of the resonators 11 and 12 to the second signal terminal 3. In other words, the number of components of the first circuit 10 that are provided between the resonators 11 and 12 and the first signal terminal 2 may be greater than the number of components of the first circuit 10 that are provided between the resonators 11 and 12 and the second signal terminal 3.

Next, an example of a circuit configuration of the second circuit 20 is described. The second circuit 20 includes inductors L21, L22, L23, and L24 and capacitors C21, C22, C23, C24, C25, C26, C27, C28, and C29.

The inductors L23 and L24 and the capacitors C21, C22, and C23 are provided in a path that extends from the first signal terminal 2 to the third signal terminal 4. The inductors L21 and L22 and the capacitors C24, C25, C28, and C29 are provided between the above-mentioned path and the ground.

One end of the capacitor C21 is connected to the first signal terminal 2. One end of the capacitor C22 is connected to the other end of the capacitor C21. One end of the capacitor C23 is connected to the other end of the capacitor C22.

One end of the capacitor C24 is connected to a connection point between the capacitor C21 and the capacitor C22. One end of the capacitor C25 is connected to a connection point between the capacitor C22 and the capacitor C23.

One end of the inductor L21 is connected to the other end of the capacitor C24. One end of the inductor L22 is connected to the other end of the capacitor C25. The other end of the inductor L21 and the other end of the inductor L22 are connected to the ground.

One end of the inductor L23 is connected to the other end of the capacitor C23. One end of the inductor L24 is connected to the other end of the inductor L23. The other end of the inductor L24 is connected to the third signal terminal 4.

The capacitor C26 is connected in parallel to the inductor L23. The capacitor C27 is connected in parallel to the inductor L24.

One end of the capacitor C28 is connected to one end of the inductor L23. One end of the capacitor C29 is connected to a connection point between the inductor L23 and the inductor L24. The other end of the capacitor C28 and the other end of the capacitor C29 are connected to the ground.

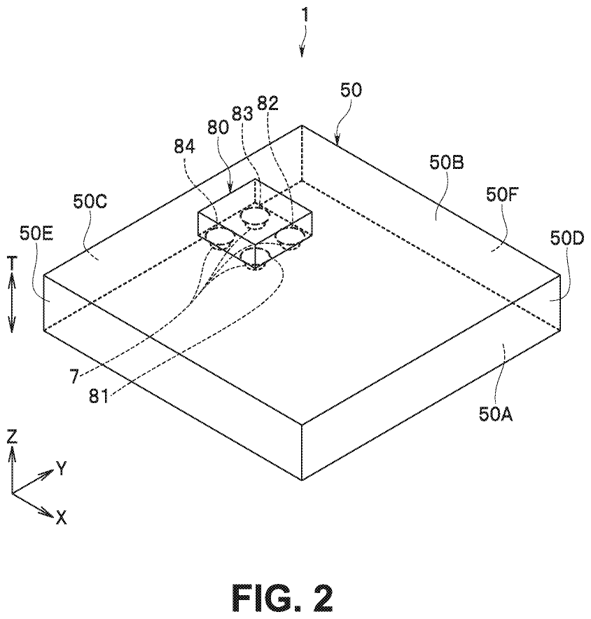

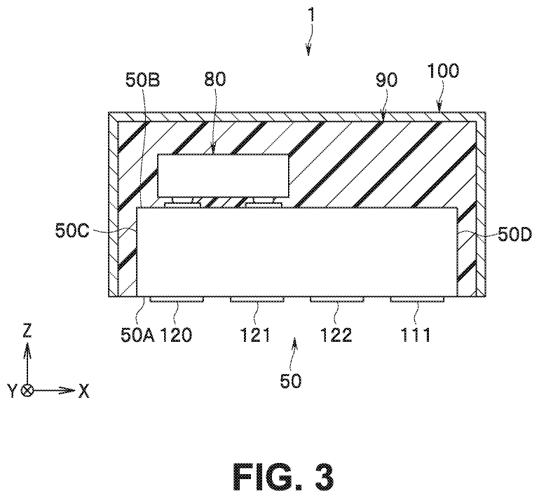

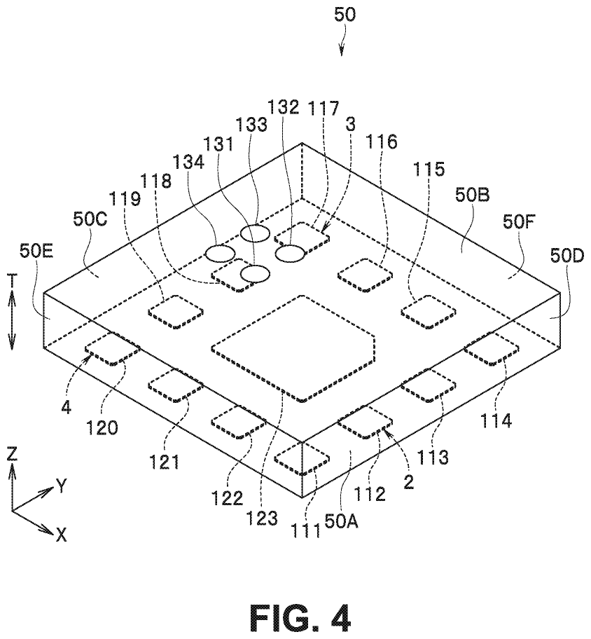

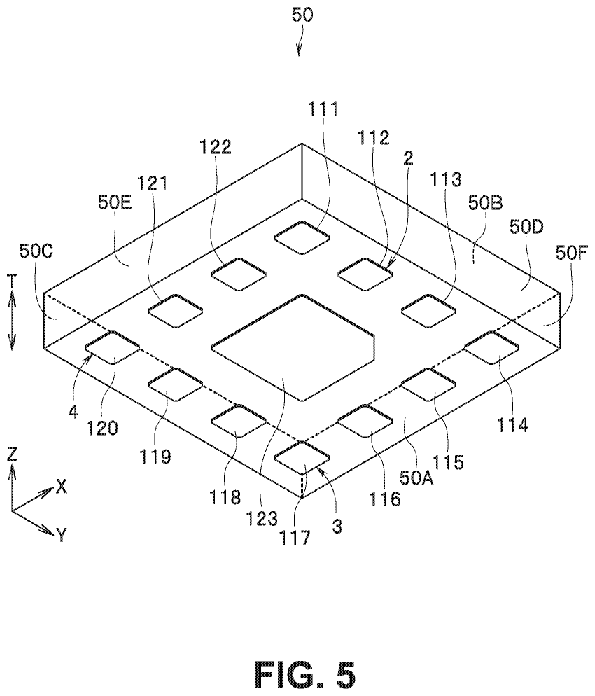

Next, with reference to FIG. 2 to FIG. 5, other configurations of the electronic component 1 are described. FIG. 2 is a perspective view showing the electronic component 1. FIG. 3 is a cross-sectional view of the electronic component 1. FIG. 4 and FIG. 5 are perspective views showing a stack of the electronic component 1.

The electronic component 1 according to the example embodiment further includes a stack 50 and a mounted component 80 that is mounted on the stack 50. The stack 50 is provided to integrate the first to third signal terminals 2 to 4, the first circuit 10, and the second circuit 20. The stack 50 includes a plurality of dielectric layers being stacked and a plurality of conductors (a plurality of conductor layers and a plurality of through holes). As such a dielectric material, for example, a low temperature co-fired ceramic (LTCC) is used.

The stack 50 includes components other than the resonators 11 and 12 among the plurality of components of the electronic component 1 shown in FIG. 1. The mounted component 80 includes the resonators 11 and 12.

The stack 50 includes a bottom surface 50A that is located at one end in a stacking direction T of the plurality of dielectric layers, a top surface 50B that is located at the other end in the stacking direction T, and four side surfaces 50C to 50F that connect the bottom surface 50A and the top surface 50B to each other. The side surfaces 50C and 50D are opposite to each other, and the side surfaces 50E and 50F are also opposite to each other. The side surfaces 50C to 50F are perpendicular to the bottom surface 50A and the top surface 50B.

Here, X, Y, and Z directions are defined as shown in FIGS. 2 to 5. The X direction, the Y direction, and the Z direction are orthogonal to one another. In the example embodiment, a direction parallel to the stacking direction T is referred to as the Z direction. The opposite directions to the X, Y, and Z directions are defined as −X, −Y, and −Z directions, respectively. The expression “as viewed in a specific direction (for example, the stacking direction T)” indicates that a target object is viewed in a specific direction or from a position separated in a direction parallel to the specific direction, in other words, a target object is viewed in a plan view. With regard to the components of the electronic component 1, a shape thereof in a plan view in the Z direction is referred to as a “planar shape”.

The bottom surface 50A is located at the end of the stack 50 in the −Z direction. The top surface 50B is located at the end of the stack 50 in the Z direction. FIG. 4 shows the stack 50 as viewed from the top surface 50B side. FIG. 5 shows the stack 50 as viewed from the bottom surface 50A side. The side surface 50C is located at the end of the stack 50 in the −X direction. The side surface 50D is located at the end of the stack 50 in the X direction. The side surface 50E is located at the end of the stack 50 in the −Y direction. The side surface 50F is located at the end of the stack 50 in the Y direction.

The resonators 11 and 12 are arranged so that an interval between the resonators 11 and 12, and the top surface 50B is smaller than an interval between the resonators 11 and 12, and the bottom surface 50A. In particular, in the example embodiment, the mounted component 80 is mounted on the top surface 50B. The mounted component 80 includes the resonators 11 and 12, and hence it can also be understood that the resonators 11 and 12 are mounted on the top surface 50B. Note that the resonators 11 and 12 may be arranged on the surface of the stack 50 or in the stack 50 as long as the above-mentioned requirements relating to the intervals are satisfied.

The stack 50 further includes a plurality of electrodes 111, 112, 113, 114, 115, 116, 117, 118, 119, 120, 121, 122, and 123 that are provided on the bottom surface 50A of the stack 50. The electrodes 111, 112, 113, and 114 are arrayed in this order in the Y direction at the positions closer to the side surface 50D than the side surface 50C. The electrodes 117, 118, 119, and 120 are arrayed in this order in the −Y direction at positions closer to the side surface 50C than the side surface 50D.

The electrodes 115 and 116 are arranged between the electrode 114 and the electrode 117 in this order in the −X direction. The electrodes 121 and 122 are arranged between the electrode 111 and the electrode 120 in this order in the X direction. The electrode 123 is arranged substantially at the center of the bottom surface 50A.

The electrode 112 corresponds to the first signal terminal 2. The electrode 117 corresponds to the second signal terminal 3. The electrode 120 corresponds to the third signal terminal 4. Each of the electrodes 111, 113 to 116, 118, 119, and 121 to 123 is connected to the ground. Each of the electrodes 111, 113 to 116, 118, 119, and 121 to 123 corresponds to a “ground terminal” in the disclosure. Therefore, the first to third signal terminals 2 to 4 and the ground terminals are provided to the bottom surface 50A of the stack 50. Note that the first to third signal terminals 2 to 4 are not limited to being provided to the bottom surface 50A of the stack 50, and are only required to be provided to the surface of the stack 50.

The stack 50 further includes electrodes 131, 132, 133, and 134 provided to the top surface 50B of the stack 50. The plurality of electrodes 131 to 134 are used for electrical connection between the stack 50 and the mounted component 80. The electrodes 131 and 132 are arranged in this order in the Y direction. The electrodes 133 and 134 are arranged ahead of the electrodes 131 and 132 in the X direction, and are arrayed in this order in the −Y direction.

The mounted component 80 further includes four electrodes 81, 82, 83, and 84. In a state where the mounted component 80 is mounted on the stack 50, the electrodes 81 to 84 face the electrode 131 to 134 of the stack 50, respectively. For example, the electrodes 81 to 84 are physically connected to the electrodes 131 to 134 with solder bumps 7.

The electronic component 1 further includes a protective layer 90. The protective layer 90 covers the mounted component 80 and the top surface 50B of the stack 50. The protective layer 90 may further cover the side surfaces 50C to 50F of the stack 50. As the material of the protective layer 90, an insulating material containing a resin material may be used. The resin material may be a thermosetting resin or a thermoplastic resin.

The electronic component 1 further includes a shield layer 100 formed of a conductive material. The shield layer 100 covers the stack 50, the mounted component 80, and the protective layer 90. The conductive material of the shield layer 100 may be pure metal composed of a single metal element, or an alloy composed of a plurality of metal elements. The shield layer 100 may include a plurality of layers formed of different conductive materials.

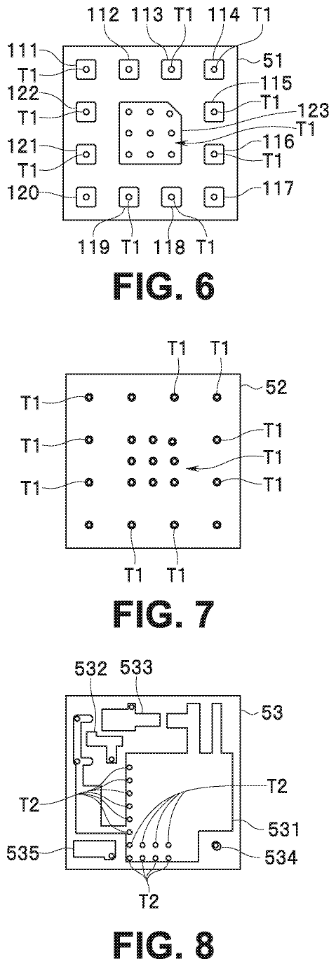

Next, with reference to FIG. 6 to FIG. 25, an example of the dielectric layers and the plurality of through holes forming the stack 50 is described. In this example, the stack 50 includes nineteen dielectric layers stacked. Hereinafter, the nineteen dielectric layers are referred to first to nineteenth dielectric layers in the order from bottom to top. The first to nineteenth dielectric layers are denoted with reference numerals 51 to 69, respectively.

In FIG. 6 to FIG. 25, a plurality of circles (a singly drawn circle and an inner circle of two concentrically drawn circles) represent the plurality of through holes. The dielectric layers 51 to 69 each include a plurality of through holes formed. The plurality of through holes are each formed by filling a hole intended for a through hole with a conductive paste. In FIG. 6 to FIG. 25, a plurality of shapes other than the plurality of circles representing the plurality of through holes represent the plurality of dielectric layers, the plurality of conductor layers, and the plurality of electrodes.

In FIG. 6 to FIG. 25, among the plurality of through holes, reference numerals are respectively assigned to a plurality of specific through holes including the plurality of through holes that form connection conductors, which are described later. A connection relation of each of the plurality of specific through holes, and a conductor layer, an electrode, or another through hole is described as a connection relation in a state where the first to nineteenth dielectric layers 51 to 69 are stacked. Among the plurality of through holes, two through holes that are vertically adjacent to each other in the stacking direction T are connected to each other.

FIG. 6 shows a patterned surface of the first dielectric layer 51. The patterned surface of the dielectric layer 51 includes the electrodes 111 to 123 formed. In the dielectric layer 51, eighteen through holes each denoted with the reference numeral T1 are formed. Each of the eighteen through holes each denoted with the reference numeral T1 is connected to any one of the electrodes 111, 113 to 116, 118, 119, and 121 to 123.

FIG. 7 shows a patterned surface of the second dielectric layer 52. In the dielectric layer 52, eighteen through holes each denoted with the reference numeral T1 are formed.

FIG. 8 shows a patterned surface of the third dielectric layer 53. The patterned surface of the dielectric layer 53 includes conductor layers 531, 532, 533, 534, and 535 formed. In the dielectric layer 53, fourteen through holes each denoted with the reference numeral T2 are formed. The fourteen through holes each denoted with the reference numeral T2 are connected to the conductor layer 531.

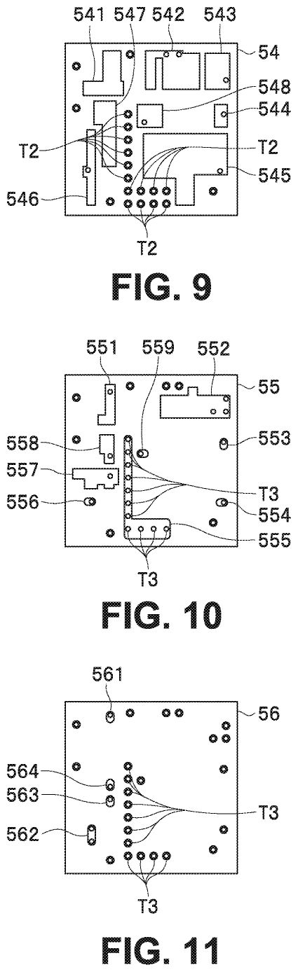

FIG. 9 shows a patterned surface of the fourth dielectric layer 54. The patterned surface of the dielectric layer 54 includes conductor layers 541, 542, 543, 544, 545, 546, 547, and 548 formed. In the dielectric layer 54, fourteen through holes each denoted with the reference numeral T2 are formed.

FIG. 10 shows a patterned surface of the fifth dielectric layer 55. The patterned surface of the dielectric layer 55 includes conductor layers 551, 552, 553, 554, 555, 556, 557, 558, and 559 formed. In the dielectric layer 55, eleven through holes each denoted with the reference numeral T3 are formed. The 11 through holes each denoted with the reference numeral T3 are connected to the conductor layer 555.

FIG. 11 shows a patterned surface of the sixth dielectric layer 56. The patterned surface of the dielectric layer 56 includes conductor layers 561, 562, 563, and 564 formed. In the dielectric layer 56, eleven through holes each denoted with the reference numeral T3 are formed.

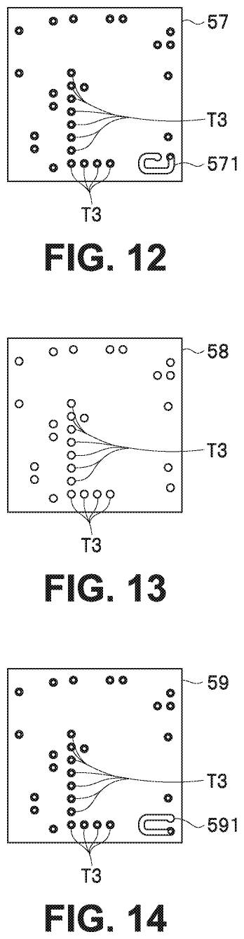

FIG. 12 shows a patterned surface of the seventh dielectric layer 57. The patterned surface of the dielectric layer 57 includes a conductor layer 571 formed. In the dielectric layer 57, eleven through holes each denoted with the reference numeral T3 are formed.

FIG. 13 shows a patterned surface of the eighth dielectric layer 58. In the dielectric layer 58, eleven through holes each denoted with the reference numeral T3 are formed.

FIG. 14 shows a patterned surface of the ninth dielectric layer 59. The patterned surface of the dielectric layer 59 includes a conductor layer 591 formed. In the dielectric layer 59, eleven through holes each denoted with the reference numeral T3 are formed.

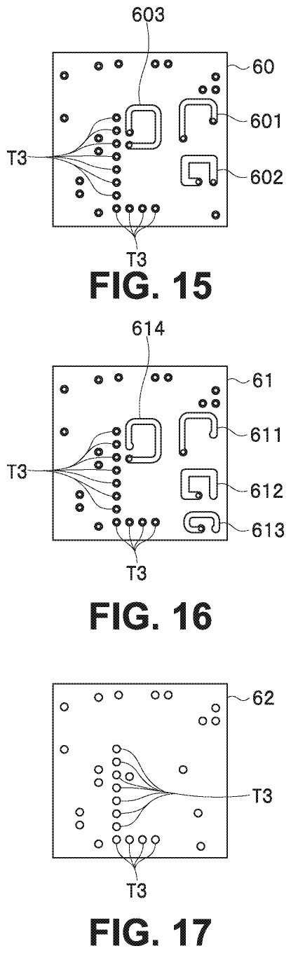

FIG. 15 shows a patterned surface of the tenth dielectric layer 60. The patterned surface of the dielectric layer 60 includes conductor layers 601, 602, and 603 formed. In the dielectric layer 60, eleven through holes each denoted with the reference numeral T3 are formed.

FIG. 16 shows a patterned surface of the eleventh dielectric layer 61. The patterned surface of the dielectric layer 61 includes conductor layers 611, 612, 613, and 614 formed. In the dielectric layer 61, eleven through holes each denoted with the reference numeral T3 are formed.

FIG. 17 shows a patterned surface of the twelfth dielectric layer 62. In the dielectric layer 62, eleven through holes each denoted with the reference numeral T3 are formed.

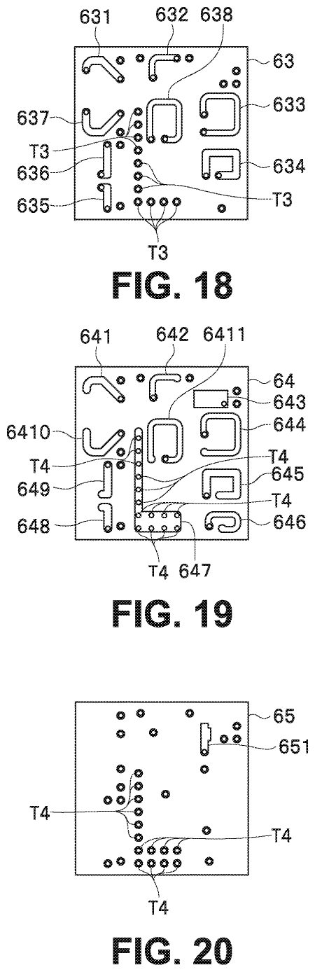

FIG. 18 shows a patterned surface of the thirteenth dielectric layer 63. The patterned surface of the dielectric layer 63 includes conductor layers 631, 632, 633, 634, 635, 636, 637, and 638 formed. In the dielectric layer 63, eleven through holes each denoted with the reference numeral T3 are formed.

FIG. 19 shows a patterned surface of the fourteenth dielectric layer 64. The patterned surface of the dielectric layer 64 includes conductor layers 641, 642, 643, 644, 645, 646, 647, 648, 649, 6410, and 6411 formed. In the dielectric layer 64, fourteen through holes each denoted with the reference numeral T4 are formed. The fourteen through holes each denoted with the reference numeral T4 are connected to the conductor layer 647.

FIG. 20 shows a patterned surface of the fifteenth dielectric layer 65. The patterned surface of the dielectric layer 65 includes a conductor layer 651 formed. In the dielectric layer 65, fourteen through holes each denoted with the reference numeral T4 are formed.

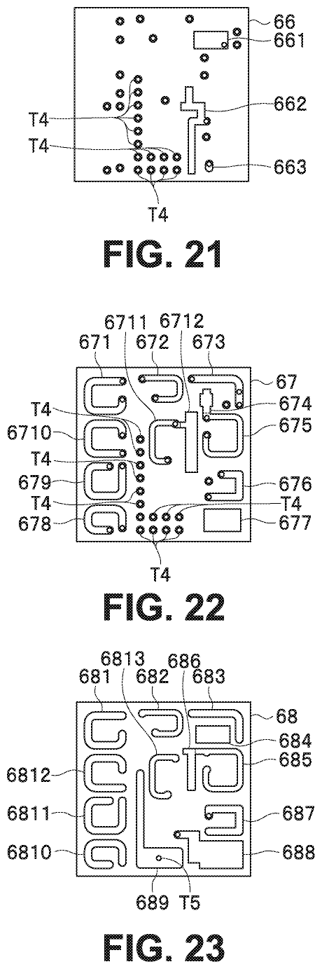

FIG. 21 shows a patterned surface of the sixteenth dielectric layer 66. The patterned surface of the dielectric layer 66 includes conductor layers 661, 662, and 663 formed. In the dielectric layer 66, fourteen through holes each denoted with the reference numeral T4 are formed.

FIG. 22 shows a patterned surface of the seventeenth dielectric layer 67. The patterned surface of the dielectric layer 67 includes conductor layers 671, 672, 673, 674, 675, 676, 677, 678, 679, 6710, 6711, and 6712 formed. The conductor layer 675 is connected to the conductor layer 674. The conductor layer 6712 is connected to the conductor layer 6711. In FIG. 22, the boundary between the conductor layer 674 and the conductor layer 675 and the boundary between the conductor layer 6711 and the conductor layer 6712 are indicated by the respective thin solid lines. In the dielectric layer 67, fourteen through holes each denoted with the reference numeral T4 are formed.

FIG. 23 shows a patterned surface of the eighteenth dielectric layer 68. The patterned surface of the dielectric layer 68 includes conductor layers 681, 682, 683, 684, 685, 686, 687, 688, 689, 6810, 6811, 6812, and 6813 formed. The conductor layer 686 is connected to the conductor layer 685. In FIG. 23, the boundary between the conductor layer 685 and the conductor layer 686 is indicated by the thin solid line. In the dielectric layer 68, the through hole T5 is formed. The through hole T5 is connected to the conductor layer 689.

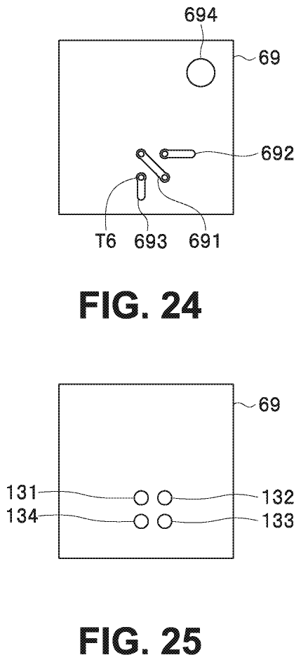

FIG. 24 shows a patterned surface of the nineteenth dielectric layer 69. The patterned surface of the dielectric layer 69 includes conductor layers 691, 692, and 693 and a mark 694 formed. In the dielectric layer 69, the through hole T6 is formed.

FIG. 25 shows a terminal formation surface being a surface opposite to the patterned surface of the nineteenth dielectric layer 69. The terminal formation surface of the dielectric layer 69 includes the electrode 131 to 134 formed.

The stack 50 shown in FIG. 2 to FIG. 5 is formed by stacking the first to nineteenth dielectric layers 51 to 69 so that the patterned surface of the first dielectric layer 51 serves as the bottom surface 50A of the stack 50 and the terminal formation surface of the nineteenth dielectric layer 69 serves as the top surface 50B of the stack 50. Note that FIG. 6 to FIG. 25 show the shapes and the arrangement of the plurality of conductor layers, the plurality of electrodes, and the plurality of through holes as viewed from the bottom surface 50A of the stack 50 side.

Each of the plurality of through holes shown in FIGS. 6 to 25 is, with the first to nineteenth dielectric layers 51 to 69 stacked, connected to a conductor layer overlapping in the stacking direction T or to another through hole overlapping in the stacking direction T. Of the plurality of through holes shown in FIGS. 6 to 25, a through hole located within an electrode or within a conductor layer is connected to the electrode or the conductor layer.

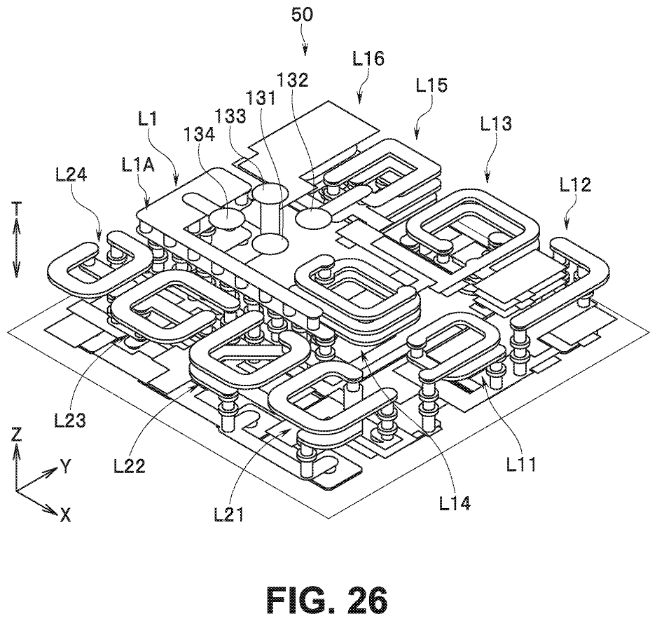

FIG. 26 shows the inside of the stack 50 formed by stacking the first to nineteenth dielectric layers 51 to 69. In the stack 50, the plurality of conductor layers and the plurality of through holes that are shown in FIG. 6 to FIG. 24 are stacked. Note that, in FIG. 26, the mark 694 is omitted.

Correspondences between the configurations of the circuits of the electronic component 1 shown in FIG. 1 and the components of the stack 50 shown in FIG. 6 to FIG. 25 are described below.

First, the components of the first circuit 10 are described. The inductor L1 includes the conductor layers 555, 647, 689, and 693 and the plurality of through holes denoted with the reference numerals T2 to T4. The plurality of through holes denoted with the reference numeral T2 are connected to the conductor layer 531. The conductor layer 531 is connected to the electrodes 111, 113 to 116, 118, 119, and 121 to 123 via the plurality of through holes denoted with the reference numeral T1.

The inductor L11 includes the conductor layers 632, 642, 672, and 682 and the plurality of through holes that connect, among the conductor layers 632, 642, 672, and 682, two conductor layers adjacent to each other at an interval in the stacking direction T. The inductor L12 includes the conductor layers 673 and 683, and the plurality of through holes that connect the conductor layer 673 and 683 to each other.

The capacitor C11 includes the conductor layers 533 and 542, and the dielectric layer 53 between those conductor layers. The capacitor C12 includes the conductor layers 542 and 552, and the dielectric layer 54 between those conductor layers. The capacitor C13 includes the conductor layers 531 and 542, and the dielectric layer 53 between those conductor layers. The capacitor C14 includes the conductor layers 531 and 543, and the dielectric layer 53 between those conductor layers.

The capacitor C15 includes the conductor layers 643, 651, 661, 674, and 684 and the dielectric layers 64 to 67 between those conductor layers. The capacitor C16 includes the conductor layers 6712 and 686, and the dielectric layer 67 between those conductor layers. The capacitor C17 includes the conductor layers 662 and 6712, and the dielectric layer 66 between those conductor layers.

The inductor L13 includes the conductor layers 601, 611, 633, 644, 675, and 685 and the plurality of through holes that connect, among the conductor layers 601, 611, 633, 644, 675, and 685, two conductor layers adjacent to each other at an interval in the stacking direction T. The inductor L14 includes the conductor layers 603, 614, 638, 6411, 6711, and 6813 and the plurality of through holes that connect, among the conductor layers 603, 614, 638, 6411, 6711, and 6813, two conductor layers adjacent to each other at an interval in the stacking direction T. The inductor L15 includes the conductor layers 602, 612, 634, 645, 676, 687, and 692 and the plurality of through holes that connect, among the conductor layer 602, 612, 634, 645, 676, 687, and 692, two conductor layers adjacent to each other at an interval in the stacking direction T.

The capacitor C18 includes the conductor layers 531 and 544, and the dielectric layer 54 between those conductor layers. The capacitor C19 includes the conductor layers 531 and 548, and the dielectric layer 54 between those conductor layers. The capacitor C110 includes the conductor layers 531 and 545, and the dielectric layer 54 between those conductor layers.

The one end of the resonator 11 is connected to the electrode 132. One of the one end of the resonator 12 and the other end of the resonator 11 is connected to the electrode 131. One of the one end of the resonator 12 and the other end of the resonator 11 is connected to the electrode 133. The other end of the resonator 12 is connected to the electrode 134. The electrode 134 is connected to the conductor layer 689 via the through hole denoted with the reference numeral T5, the conductor layer 693, and the through hole denoted with the reference numeral T6.

The capacitor C111 includes the conductor layers 662 and 688, and the dielectric layers 66 and 67 between those conductor layers. The capacitor C112 includes the conductor layers 677 and 688, and the dielectric layer 68 between those conductor layers.

The inductor L16 includes the conductor layers 571, 591, 613, and 646 and the plurality of through holes that connect, among the conductor layers 571, 591, 613, and 646, two conductor layers adjacent to each other at an interval in the stacking direction T.

Next, the components of the second circuit 20 are described. The capacitor C21 includes the conductor layers 533 and 541, and the dielectric layer 53 between those conductor layers. The capacitor C22 includes the conductor layers 532 and 541, and the dielectric layer 53 between those conductor layers. The capacitor C23 includes the conductor layers 547 and 557, and the dielectric layer 54 between those conductor layers.

The capacitor C24 includes the conductor layers 541 and 551, and the dielectric layer 54 between those conductor layers. The capacitor C25 includes the conductor layers 547 and 558, and the dielectric layer 54 between those conductor layers.

The inductor L21 includes the conductor layers 631, 641, 671, and 681 and the plurality of through holes that connect, among the conductor layers 631, 641, 671, and 681, two conductor layers adjacent to each other at an interval in the stacking direction T. The inductor L22 includes the conductor layers 637, 6410, 6710, and 6812 and the plurality of through holes that connect, among the conductor layers 637, 6410, 6710, and 6812, two conductor layers adjacent to each other at an interval in the stacking direction T.

The inductor L23 includes the conductor layers 636, 649, 679, and 6811 and the plurality of through holes that connect, among the conductor layers 636, 649, 679, and 6811, two conductor layers adjacent to each other at an interval in the stacking direction T. The inductor L24 includes the conductor layers 635, 648, 678, and 6810 and the plurality of through holes that connect, among the conductor layers 635, 648, 678, and 6810, two conductor layers adjacent to each other at an interval in the stacking direction T.

The capacitor C26 includes the conductor layers 546 and 557, and the dielectric layer 54 between those conductor layers. The capacitor C27 includes the conductor layers 535 and 546, and the dielectric layer 53 between those conductor layers.

The capacitor C28 includes the conductor layers 531 and 557, and the dielectric layers 53 and 54 between those conductor layers. The capacitor C29 includes the conductor layers 531 and 546, and the dielectric layer 53 between those conductor layers.

The electronic component 1 further includes a connection conductor L1A that connects the resonator 12 to the electrodes 111, 113 to 116, 118, 119, and 121 to 123, in other words, the ground terminals. The connection conductor L1A is arranged in the stack 50. The configuration of the connection conductor L1A is described later in detail.

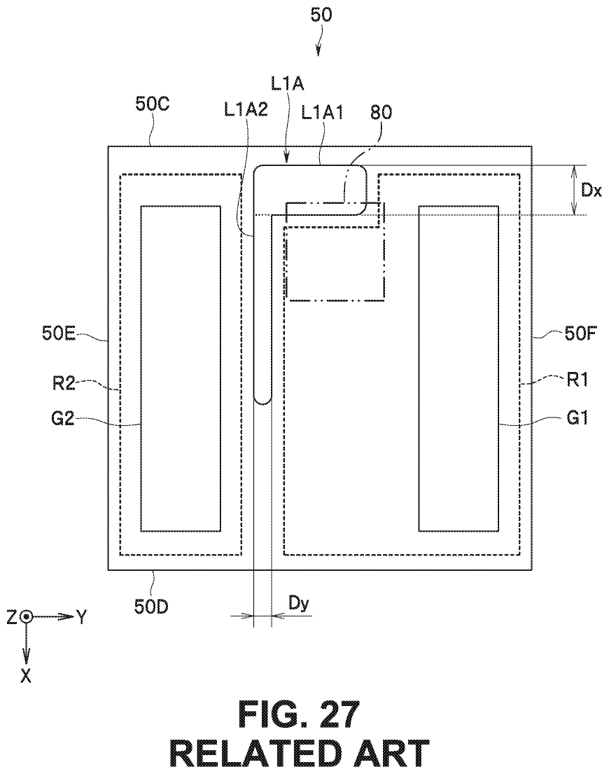

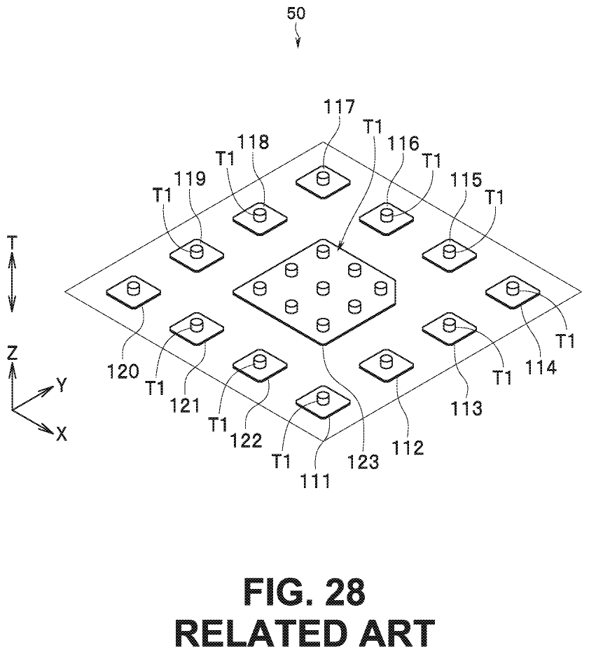

Next, with reference to FIG. 1 to FIG. 30, structural features of the electronic component 1 according to the example embodiment are described. FIG. 27 is a plan view showing a part of the stack 50. FIG. 28 to FIG. 30 are perspective views showing a part of the stack 50. Note that, in FIG. 28 to FIG. 30, for convenience, the dimension of the stack 50 in the stacking direction T is shown in an enlarged manner.

As shown in FIG. 27, the stack 50 further includes a first conductor group G1 forming at least a part of the first circuit 10 and a second conductor group G2 forming at least a part of the second circuit 20. The first conductor group G1 includes a plurality of conductors forming the inductors L11 to L16 shown in FIG. 1. The second conductor group G2 includes a plurality of conductors forming the inductors L21 to L24 shown in FIG. 1.

The first conductor group G1 may further include at least some of a plurality of conductors forming the capacitors C11 to C112. The second conductor group G2 may further include at least some of a plurality of conductors forming the capacitors C21 to C29.

In FIG. 27, a region surrounded by the broken line denoted with the reference numeral R1 indicates a first region R1 in which the first conductor group G1 is arranged. A region surrounded by the broken line denoted with the reference numeral R2 indicates a second region R2 in which the second conductor group G2 is arranged. The first region R1 may be a region along the side surface 50F. The second region R2 may be a region along the side surface 50E. The first conductor group G1 is arranged in the first region R1. The second conductor group G2 is arranged in the second region R2. The first conductor group G1 and the second conductor group G2 are arrayed in a direction orthogonal to the stacking direction T. In the example embodiment, the first conductor group G1 and the second conductor group G2 are arrayed in a direction parallel to the Y direction.

Herein, a region between the first region R1 and the second region R2 is referred to as an intermediate region. Among the plurality of conductors forming the first circuit 10, at least one conductor that is not included in the first conductor group G1 is not limited to being arranged in the first region R1, and may be arranged in at least one of the second region R2 and the intermediate region. Among the plurality of conductors forming the second circuit 20, at least one conductor that is not included in the second conductor group G2 is not limited to being arranged in the second region R2, and may be arranged in at least one of the first region R1 and the intermediate region. At least one conductor that is not included in the first conductor group G1 or at least one conductor that is not included in the second conductor group G2 may be at least one conductor that is connected to the ground, for example.

The mounted component 80 may be arranged so that an interval between the mounted component 80 and the side surface 50C is smaller than an interval between the mounted component 80 and the side surface 50D. The mounted component 80 may be arranged so as to overlap with the first region R1 in a plan view in the stacking direction T. The mounted component 80 may be arranged so as not to overlap with the second region R2 in a plan view in the stacking direction T.

Each of the first conductor group G1 and the second conductor group G2 is not arranged between the mounted component 80 and the side surface 50C in a plan view in the stacking direction T.

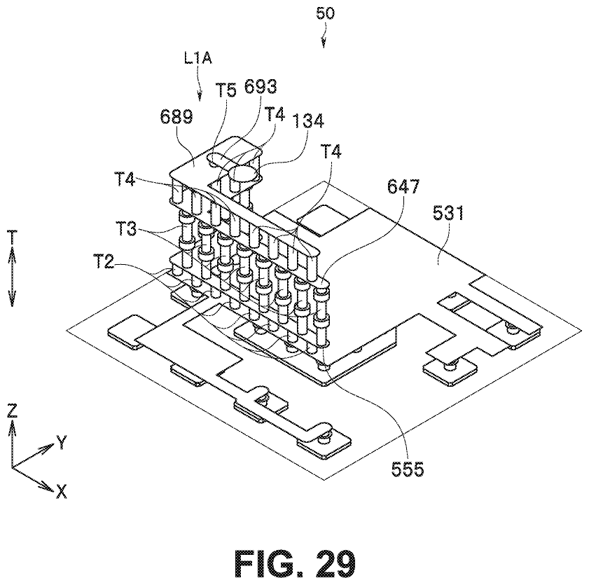

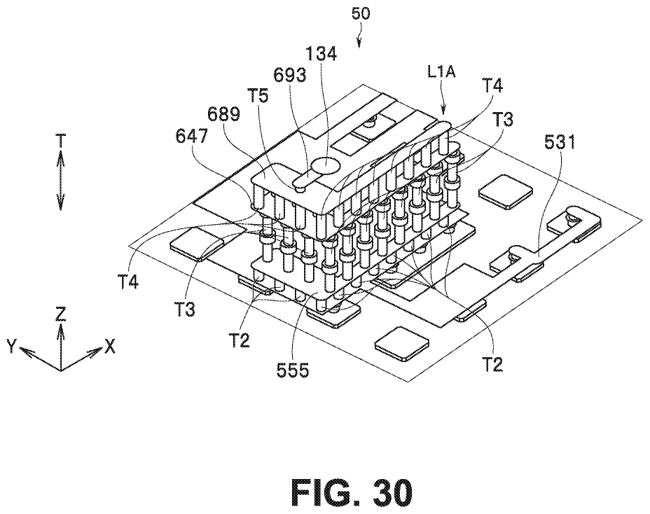

Next, the connection conductor L1A is described in detail. First, a configuration of the connection conductor L1A is described. As shown in FIG. 29 and FIG. 30, the connection conductor L1A includes a plurality of columnar conductors T2, a plurality of columnar conductors T3, a plurality of columnar conductors T4, and the conductor layers 555, 647, and 689. The plurality of columnar conductors T2, the plurality of columnar conductors T3, and the plurality of columnar conductors T4 are arrayed in this order in the Z direction.

Each of the plurality of columnar conductors T2 is configured by connecting, among the plurality of through holes denoted with the reference numeral T2 shown in FIG. 8 and FIG. 9, two vertically-adjacent through holes in series. Each of the plurality of columnar conductors T2 extends in a direction parallel to the stacking direction T. The plurality of columnar conductors T2 are arrayed in parallel. In the example shown in FIG. 29 and FIG. 30, the number of the plurality of columnar conductors T2 is fourteen.

The plurality of columnar conductors T2 are connected to the conductor layer 555. The plurality of columnar conductors T2 are electrically connected in parallel by the conductor layers 531 and 555.

Each of the plurality of columnar conductors T3 is configured by connecting, among the plurality of through holes denoted with the reference numeral T3 shown in FIG. 10 to FIG. 18, two vertically-adjacent through holes in series. Each of the plurality of columnar conductors T3 extends in a direction parallel to the stacking direction T. The plurality of columnar conductors T3 are arrayed in parallel. In the example shown in FIG. 29 and FIG. 30, the number of the plurality of columnar conductors T3 is eleven.

The plurality of columnar conductors T3 are connected to the conductor layers 555 and 647. The plurality of columnar conductors T3 are electrically connected in parallel by the conductor layers 555 and 647.

Each of the plurality of columnar conductors T4 is configured by connecting, among the plurality of through holes denoted with the reference numeral T4 shown in FIG. 19 to FIG. 22, two vertically-adjacent through holes in series. Each of the plurality of columnar conductors T4 extends in a direction parallel to the stacking direction T. The plurality of columnar conductors T4 are arrayed in parallel. In the example shown in FIG. 29 and FIG. 30, the number of the plurality of columnar conductors T4 is fourteen.

The plurality of columnar conductors T4 are connected to the conductor layers 647 and 689. The plurality of columnar conductors T4 are electrically connected in parallel by the conductor layers 647 and 689.

The connection conductor L1A electrically connects the through hole denoted with the reference numeral T6 to the conductor layer 531. The other end of the resonator 12 is electrically connected to the electrode 134. The electrode 134 is electrically connected to the through hole denoted with the reference numeral T6 via the through hole denoted with the reference numeral T5 and the conductor layer 693. The electrodes 111, 113 to 116, 118, 119, and 121 to 123, in other words, the ground terminals are electrically connected to the conductor layer 531 via the plurality of columnar conductors T1. Therefore, substantially, the connection conductor L1A electrically connects the resonator 12 to the ground terminals.

Note that a mode in which two components are electrically connected to each other includes a case where the two components are connected in series via a conductor and a case where the two components are connected in series via an inductor. Meanwhile, a mode in which a capacitor is present between two components, specifically, a case where two components are connected via a capacitor is not included in the mode in which two components are electrically connected to each other.

As described above, the inductor L1 includes the conductor layers 555, 647, 689, and 693 and the plurality of through holes denoted with the reference numerals T2 to T4. The conductor layers 555, 647, 689, and 693 and the plurality of through holes denoted with the reference numerals T2 to T4 form the connection conductor L1A. Therefore, the inductor L1 includes the connection conductor L1A. The inductor L1 electrically connects the resonator 12 to the ground terminals.

The connection conductor L1A includes a first part L1A1 and a second part L1A2. In FIG. 27, the boundary between the first part L1A1 and the second part L1A2 is indicated by the dotted line. The first part L1A1 is arranged so that an interval between the first part L1A1 and the side surface 50C is smaller than an interval between the first part L1A1 and the side surface 50D. The second part L1A2 extends from the first part L1A1 toward the side surface 50D.

In FIG. 27, a symbol Dx indicates a dimension of the first part L1A1 in a direction perpendicular to the side surface 50C, in other words, a direction parallel to the X direction. A symbol Dy indicates a dimension of the second part L1A2 in a direction parallel to the side surface 50C, in other words, a direction parallel to the Y direction. The dimension Dx is larger than the dimension Dy. The dimension Dx may be smaller than the dimension of the second part L1A2 in a direction parallel to the X direction. The dimension Dy may be smaller than the dimension of the first part L1A1 in a direction parallel to the Y direction.

Next, the arrangement of the connection conductor L1A is described. The connection conductor L1A is arranged in the region between the first region R1 and the second region R2, in other words, the intermediate region. The second part L1A2 extends in a direction intersecting with a direction in which the first conductor group G1 and the second conductor group G2 are arrayed, so as to be interposed between at least a part of the first conductor group G1 and at least a part of the second conductor group G2. In the example shown in FIG. 27, the second part L1A2 extends in a direction parallel to the Y direction.

The first part L1A1 may overlap with or may not overlap with the mounted component 80 in a plan view in the stacking direction T. In the example shown in FIG. 27, a part of the first part L1A1 overlaps with the mounted component 80 in a plan view in the stacking direction T. The other part of the first part L1A1 is arranged between the mounted component 80 and the side surface 50C in a plan view in the stacking direction T. An area of a planar shape of the above-mentioned part of the first part L1A1 may be smaller than an area of a planar shape of the above-mentioned other part of the first part L1A1.

The second part L1A2 may overlap with or may not overlap with the mounted component 80 in a plan view in the stacking direction T. In the example shown in FIG. 27, the second part L1A2 is arranged between the mounted component 80 and the side surface 50E in a plan view in the stacking direction T.

In the example embodiment, in the first region R1, the inductors L12, L13, L15, and L16 of the first circuit 10 are arrayed in this order from the side surface 50D toward the side surface 50C. The inductor L11 of the first circuit 10 is arranged between the inductor L12 and the second region R2. The inductor L14 of the first circuit 10 is arranged between the inductor L13 and the second region R2. In the second region R2, the inductors L21, L22, L23, and L24 of the second circuit 20 are arrayed in this order from the side surface 50D toward the side surface 50C. The first part L1A1 may be interposed between the inductor L16 and the inductor L24. The second part L1A2 may be interposed between the inductors L14 and L15 and the inductors L22 and L23. The second part L1A2 may be or may not be interposed between the inductor L14 and the inductor L21.

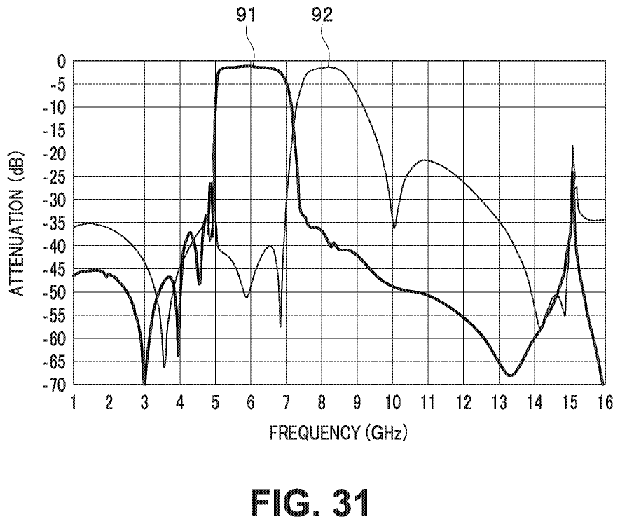

Next, an example of characteristics of the electronic component 1 is described. FIG. 31 is a characteristic chart showing an example of pass attenuation characteristics of the electronic component 1. In FIG. 31, the horizontal axis indicates frequency and the vertical axis indicates attenuation. In FIG. 31, the curve line denoted with the reference numeral 91 indicates pass attenuation characteristics between the first signal terminal 2 and the second signal terminal 3. The curve line denoted with the reference numeral 92 indicates pass attenuation characteristics between the first signal terminal 2 and the third signal terminal 4. It can be understood from FIG. 31 that the electronic component 1 according to the example embodiment can achieve sufficient characteristics in practical use as a branching filter.

Next, the operation and effects of the electronic component 1 according to the example embodiment are described. In the example embodiment, the connection conductor L1A connects the resonator 12 to the ground terminals (the electrodes 111, 113 to 116, 118, 119, and 121 to 123). In particular, in the example embodiment, the connection conductor L1A extends through the stack 50.

Depending on the specifications of the first circuit 10 including the resonator 12, it is required to sufficiently reduce the inductance of the connection conductor L1A in some cases. In other words, when the inductance of the connection conductor L1A (the inductor L1) is large, the desired characteristics cannot be achieved in some cases. In order to reduce the inductance of the connection conductor L1A, it is conceivable to reduce the dimension of the stack 50 in the stacking direction T and reduce the dimension of the connection conductor L1A in the stacking direction T. However, inside the stack 50, the components of the first circuit 10 other than the resonators 11 and 12 and the components of the second circuit 20 are provided. Thus, it is difficult to reduce the dimension of the stack 50 in the stacking direction T while maintaining the characteristics of the electronic component 1 as a branching filter.

In contrast, in the example embodiment, the connection conductor L1A includes the plurality of columnar conductors T2, the plurality of columnar conductors T3, the plurality of columnar conductors T4, and the conductor layers 555, 647, and 689. The plurality of columnar conductors T2, the plurality of columnar conductors T3, and the plurality of columnar conductors T4 are respectively arrayed in parallel. The plurality of columnar conductors T2 and the plurality of columnar conductors T3 are connected to the conductor layer 555. The plurality of columnar conductors T3 and the plurality of columnar conductors T4 are connected to the conductor layer 647. The plurality of columnar conductors T4 are connected to the conductor layer 689. With this, according to the example embodiment, the inductance of the connection conductor L1A can be reduced more as compared to a case where the connection conductor L1A is formed by the plurality of through holes that are arrayed in the stacking direction T but not arrayed in a direction orthogonal to the stacking direction T in place of the plurality of columnar conductors T2, the plurality of columnar conductors T3, and the plurality of columnar conductors T4. With this, according to the example embodiment, it is possible to suppress a problem that the desired characteristics cannot be achieved due to the inductance of the connection conductor L1A.

Note that the disclosure is not limited to the foregoing example embodiment, and various modifications may be made thereto. For example, the number and the arrangement of each of the plurality of columnar conductors T2, the plurality of columnar conductors T3, and the plurality of columnar conductors T4 are not limited to the examples shown in the example embodiment, and may be freely selected. For example, the number of the plurality of columnar conductors T3 may be the same as the number of the plurality of columnar conductors T2 and the number of the plurality of columnar conductors T4, or may be greater than the number of the plurality of columnar conductors T2 and the number of the plurality of columnar conductors T4.

The resonator 12 may be a resonator configured by an element other than an acoustic wave element. In such a case, the resonator may be mounted on the top surface 50B of the stack 50, or may be arranged in the stack 50. Even when the resonator configured by an acoustic wave element or an element other than an acoustic wave element is arranged in the stack 50, a problem caused by the connection conductor can be suppressed by connecting the resonator to the ground terminals by the connection conductor of the disclosure.

A capacitor may be provided between the resonator 12 and the ground terminals. In such a case, the capacitor may be connected to the resonator 12 or the ground terminals by at least a part of the connection conductor.

The electronic component of the disclosure is not limited to a branching filter, and may be a filter such as a high-pass filter, a low-pass filter, and a band-pass filter.

As described above, an electronic component according to an embodiment of the disclosure includes a first signal terminal, a second signal terminal, a ground terminal connected to a ground, a resonator provided between a path from the first signal terminal to the second signal terminal and the ground in a circuit configuration, and a connection conductor that includes a plurality of columnar conductors arrayed in parallel and a conductor layer connected to the plurality of columnar conductors, and connects the resonator to the ground terminal.

The electronic component according to the embodiment of the disclosure may further include a stack including a plurality of dielectric layers stacked. The connection conductor may be arranged in the stack. Each of the plurality of columnar conductors may extend in a direction parallel to a stacking direction of the plurality of dielectric layers. The stack may include a bottom surface located at one end in the stacking direction and a top surface located at the other end. The ground terminal may be arranged on the bottom surface. The resonator may be arranged so that an interval between the resonator and the top surface is smaller than an interval between the resonator and the bottom surface. The electronic component according to the embodiment of the disclosure may further include a mounted component that is mounted on the top surface. The first signal terminal and the second signal terminal may be arranged on a surface of the stack. The mounted component may include the resonator. The resonator may include an acoustic wave element.

The electronic component according to the embodiment of the disclosure may further include an inductor provided between the resonator and the ground in the circuit configuration. The inductor may include a connection conductor.

The electronic component according to the embodiment of the disclosure may further include a third signal terminal, a first circuit that is provided between the first signal terminal and the second signal terminal in the circuit configuration, and is configured to selectively cause a signal having a frequency within a first passband to pass through, and a second circuit that is provided between the first signal terminal and the third signal terminal in the circuit configuration, and is configured to selectively cause a signal having a frequency within a second passband to pass through. The electronic component may further include a stack including a plurality of dielectric layers stacked. The connection conductor may be arranged in the stack. The plurality of columnar conductors may extend in a direction parallel to a stacking direction of the plurality of dielectric layers. The stack may include a first conductor group forming at least a part of the first circuit and a second conductor group forming at least a part of the second circuit. The first conductor group may be arranged in a first region. The second conductor group may be arranged in a second region. The connection conductor may be arranged between the first region and the second region.

In the electronic component of the disclosure, the connection conductor includes the plurality of columnar conductors arrayed in parallel and the conductor layer connected to the plurality of columnar conductors. With this, according to the disclosure, an electronic component that can suppress a problem caused by a connection conductor can be achieved.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. An electronic component comprising:
a first signal terminal;
a second signal terminal;
a ground terminal connected to a ground;
a resonator provided between a path from the first signal terminal to the second signal terminal and the ground in a circuit configuration; and
a connection conductor that includes a plurality of columnar conductors arrayed in parallel and a conductor layer connected to the plurality of columnar conductors, and connects the resonator to the ground terminal.

2. The electronic component according to claim 1 further comprising:
a stack including a plurality of dielectric layers stacked, wherein
the connection conductor is arranged in the stack, and
each of the plurality of columnar conductors extends in a direction parallel to a stacking direction of the plurality of dielectric layers.

3. The electronic component according to claim 2, wherein
the stack includes a bottom surface located at one end in the stacking direction and a top surface located at the other end,
the ground terminal is arranged on the bottom surface, and
the resonator is arranged so that an interval between the resonator and the top surface is smaller than an interval between the resonator and the bottom surface.

4. The electronic component according to claim 3 further comprising:
a mounted component that is mounted on the top surface, wherein
the first signal terminal and the second signal terminal are arranged on a surface of the stack, and
the mounted component includes the resonator.

5. The electronic component according to claim 4, wherein
the resonator includes an acoustic wave element.

6. The electronic component according to claim 1 further comprising:
an inductor provided between the resonator and the ground in the circuit configuration.

7. The electronic component according to claim 6, wherein
the inductor includes the connection conductor.

8. The electronic component according to claim 1 further comprising:
a third signal terminal;
a first circuit that is provided between the first signal terminal and the second signal terminal in the circuit configuration, and is configured to selectively cause a signal having a frequency within a first passband to pass through; and
a second circuit that is provided between the first signal terminal and the third signal terminal in the circuit configuration, and is configured to selectively cause a signal having a frequency within a second passband to pass through.

9. The electronic component according to claim 8 further comprising:
a stack including a plurality of dielectric layers stacked, wherein
the connection conductor is arranged in the stack,
the plurality of columnar conductors extend in a direction parallel to a stacking direction of the plurality of dielectric layers,
the stack includes a first conductor group forming at least a part of the first circuit and a second conductor group forming at least a part of the second circuit,
the first conductor group is arranged in a first region,
the second conductor group is arranged in a second region, and
the connection conductor is arranged between the first region and the second region.

10. The electronic component according to claim 9, wherein
the first conductor group and the second conductor group are arrayed in a direction orthogonal to the stacking direction, and at least a part of the connection conductor extends along a direction orthogonal to a direction in which the first conductor group and the second conductor group are arrayed.
